(19) United States
(12) Patent Application Publication
(10) Pub. No.: US 2006/0042755 A1
(43) Pub. Date: Mar. 2, 2006

(54) Large surface area dry etcher

(75) Inventors: Scott H. Holmberg, Escondido, CA (US); Olivier Postel, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: PlasmaMed, LLC, Cupertino, CA (US)

(21) Appl. No.: 11/215,534

(22) Filed: Aug. 29, 2005

Related U.S. Application Data
(60) Provisional application No. 60/605,648, filed on Aug. 30, 2004.

(51) Int. Cl. C23F 1/00; H01L 21/306

(52) U.S. Cl. 156/345.1; 438/706; 216/67

(57) ABSTRACT

A dry etcher includes a process chamber configured to process a substrate therein using plasma; a substrate supporter to support the substrate; an inner chamber wall maintained at a high temperature and at least one magnetron provided in close proximity to the substrate to generate a local uniform high density plasma. The outer chamber wall provides vacuum integrity and is kept at low enough temperature to maintain vacuum integrity and to ensure safe operation of the machine. The dry etcher further includes a radio-frequency (RF) power source coupled to the substrate supporter, wherein the plasma is generated by the RF power applied to the substrate supporter and a magnetic field generated by the magnetron.

### CROSS REFERENCE TO RELATED APPLICATION

The present application claims priority to U.S. Provisional Application No. 60/605,648, filed on Aug. 30, 2004, which is incorporated by reference.

### BACKGROUND OF THE INVENTION

The present invention relates to plasma enhanced methods and apparatus for dry etching of various materials including metals and dielectrics.

In the flat panel industry, certain materials, e.g., Indium Tin Oxide (ITO), are often wet etched because of problems associated with the available dry etching technologies. The issues with wet etch lie mostly with the quantity and toxicity of the wet chemicals used. They are costly and environmentally unfriendly. Also wet chlorine-based etches also tend to undercut the photoresist pattern and attack underlying materials, e.g., aluminum alloys, during the wet etch process. The control of the critical dimension on large panels is becoming more difficult as the pixel density increases.

The current dry etching tools used for ITO predominantly use hydrogen iodide as a chemical precursor, which is inherently unstable and forms volatile byproducts that do not easily accumulate on the chamber walls. Unfortunately, it provides non-uniform etching. The preferred chemistry to etch ITO is chlorine based; however, the byproducts of the etch have low volatility and tend to accumulate on the chamber walls. As these byproducts accumulate and become thicker, the film stress builds up and the byproducts begin to flake off the chamber walls, causing these falling flakes or particles to contaminate the substrates that are being processed in the etch chamber. As a result, the conventional dry etcher requires frequent preventative maintenance to remove the byproduct build-up on the wall, which increases the cost of ownership and the equipment down-time.

### BRIEF SUMMARY OF THE INVENTION

The present invention relates to dry etch apparatuses and etch methods thereof. In one embodiment, a dry etcher includes a heated inner wall or shell to maintain a high wall temperature during processing. The dry etcher also includes magnetrons to generate high density plasma and facilitate the etch process. The present apparatus and method may be used in many different applications, e.g., may be used to etch metals or dielectrics. The dry etcher may also be used to etch materials on a large surface area (e.g., flat panels).

One or more embodiments of the present invention address byproduct contamination issues associated with the dry etching process, particularly those associated with etching metals deposited on a large surface area. The present apparatus and method enable the use of chemical precursors other than hydrogen iodide to etch ITO films. For example, chlorine, which is very stable, is used to etch ITO according to one embodiment of the present invention.

In one embodiment, a dry etcher is described that is configured to etch ITO using chlorine-based etchant. The etcher is also configured to minimize the byproduct deposition on the chamber walls by keeping the chamber wall temperature high during the etch process to keep the byproducts vaporized. The apparatus is equipped with a chamber wall that can be heated to high temperature. In the present embodiment, the etcher is provided with an inner wall and outer wall, where the inner wall is configured to be heated to high temperature, e.g., 200° Celsius or more.

The etcher generates a high density plasma using a combination of radio frequency (RF) and magnetron sources. In one implementation, the magnetron is linear in shape and scanned across the substrate to effectively etch substrates (or panels) having large surfaces. In another implementation, a plurality of magnetrons are used to reduce the scanning length and decrease the etch time. A secondary plasma source can also be mounted opposite to the substrate to predissociate the gas. The etch control is attained by adjusting, amongst others: (1) the RF power to the substrate, (2) the shape and strength of the magnetic field from the magnetron(s), and (3) the RF power to secondary (optional) plasma source. Although the apparatus of this implementation is configured to etch ITO using chlorine as a precursor, the apparatus may be used to etch other types of films or materials. The apparatus can process substrates either in horizontal, vertical or intermediate orientation according to application.

In one embodiment, a dry etch includes a plasma generation device. The plasma may be generated by two, three or more power sources depending on the selected configuration. The plasma sources include (i) a RF powered substrate holder and (ii) a planar TCP (Transformer Coupled Plasma) or ICP (Inductively Coupled Plasma) RF powered antenna. A magnetron generates a localized magnetic field over different regions of the substrate as the magnetron is scanned across the substrate. This magnetic field confines the plasma and increases its density to generate a high density plasma that is used to etch the substrate or films thereof.

The dry etcher includes a substrate holder that is powered with RF energy. The RF energy applied to the substrate may be adjusted to control the etch process. That is, the energy at which the ions impinge on the substrate is controlled by adjusting the power delivered to the substrate holder. The magnetic field generated by a single or multiple linear permanent or electromagnets increases the plasma density locally. One or more magnets are scanned across the substrate to process large areas. A plurality of linear magnets may be used to cover shorter scan distances to provide higher throughput. The shape and strength of the magnetic field can be adjusted by modifying the magnet geometry and distance to the substrate. The magnetic field in turn affects the plasma density. The shape of the magnetic field can be tailored to render the electric field lines mostly uniform and parallel to the substrate, so that the ions are driven normally to the substrate to provide vertical or anisotropic etch. In the present implementation, the magnet is placed beneath the substrate holder. In other implementations, the magnet may be placed at other locations.

In one embodiment, a dry etcher is configured to provide a remote plasma (or additional high density plasma) above the substrate in order to predissociate the gas. Such a plasma can be a TCP or ICP plasma generated through a dielectric wall or a single or series of plasma sources, such as hollow cathodes, helicon and electron cyclotron resonance (ECR). The power applied to the remote plasma controls the gas dissociation and the resulting overall plasma density of the system.

A dry etcher of the present embodiment is configured to provide an improved byproduct management over the conventional dry etcher. The present dry etcher removes the etch byproducts from the chamber using turbomolecular pumps and cold traps attached to the process chamber. In order to reduce the deposition of the etching byproducts on the wall, the process chamber is constructed with single or double heated walls, which can reach 300° Celsius or more, depending on the application. The walls are heated by resistive heaters or by radiation, such as infrared lamps. The walls are located sufficiently far from the surface of the substrate in order to reduce plasma/wall interactions and/or heating of the substrate. The chamber walls are made of materials that are compatible with the chemistries used for etching. Such materials can be, but are not limited to, anodized aluminum, ceramic or other materials coated with chemical resistant films. Non-reacting gas may be injected between the inner and outer chamber walls in order to prevent back-streaming of etch byproducts in unwanted areas.

In one embodiment, a dry etcher includes a process chamber configured to process a substrate therein using plasma; a substrate supporter to support the substrate; and at least one magnetron provided in close proximity to the substrate and direct charged particles from the plasma to the substrate to etch the substrate. The dry etcher further includes a radio-frequency (RF) power source coupled to the substrate supporter, wherein the plasma is generated by the RF power applied to the substrate supporter and a magnetic field generated by the magnetron. The magnetron is provided below the substrate supporter and is configured to be scanned across the substrate, the substrate including a panel having a large surface area of at least 100 millimeter in a given direction and up to a few meters. The first chamber wall is configured to be heated to 230° Celsius preferably for ITO to keep most of the byproducts vaporized until they are removed from the process chamber, whereas the outer chamber wall and the substrate supporter are actively cooled. The first chamber wall is made of conductive material.

The dry etcher further comprises a second chamber wall provided outside of the first chamber wall, the first chamber wall being an inner wall and the second chamber wall being an outer wall. The first or inner chamber wall confines the plasma and defines the process chamber. A thermal insulator is provided between the first and second chamber walls. The second chamber wall provides vacuum integrity and is kept at low enough temperature to maintain vacuum integrity and to ensure safe operation of the machine. A lower chamber is provided below the process chamber, the lower chamber housing the magnetron. The dry etcher includes a plurality of magnetrons, each being configured to scan a selected region of the substrate.

The dry etcher of claim further comprising an upper chamber provided above the process chamber, the upper chamber being configured to generated plasma therein; and a plurality of holes provided on an upper side of the first chamber wall to enable portions of the plasma to be injected into the process chamber.

In another embodiment, a plasma etcher configured to etch a substrate having a large surface area includes a process chamber configured to etch a substrate therein using plasma, the substrate including a panel and an Indium Tin Oxide (ITO) film; a substrate supporter to support the substrate; a first chamber wall defining the process chamber and being configured to be heated to a high temperature, the first chamber wall comprising conductive material; and at least one magnetron provided in close proximity to the substrate and direct charged particles from the plasma to the substrate to etch the substrate.

In yet another embodiment, a method for etching a substrate having a large surface area includes providing the substrate on a substrate support in an etch chamber, the etch chamber having a first chamber wall; heating the first chamber wall to a given temperature that is sufficiently high to keep most of etch byproducts vaporized until they are removed from the etch chamber, so that byproduct accumulation on the first chamber wall is reduced; generating plasma using at least one magnetron and a radio-frequency power source, the magnetron being provided below the substrate; and etching the substrate using the generated plasma.

### BRIEF DESCRIPTION OF THE DRAWINGS

FIG. 1 illustrates a simplified diagram of a plasma etcher including an inductively coupled plasma source.

FIG. 2 illustrates a simplified dry etcher (or plasma etcher) that is configured to maintain a high inner wall temperature during the etch process according to one embodiment of the present invention.

FIG. 3 illustrates a simplified plasma etcher or apparatus that is configured to maintain a high inner wall temperature during the etch process according to another embodiment of the present invention.

### DETAILED DESCRIPTION OF THE INVENTION

The present invention relates to a dry etcher and methods for etching materials using the etcher. The dry etcher may be a high density plasma etcher and may be used to etch various materials including metal and dielectrics and may also be used to etch films or materials on a large surface area, e.g., flat panels. In one embodiment, a dry etcher is configured to maintain a high process chamber temperature (or inner wall temperature) during etch process to reduce byproduct deposition on the wall. In another embodiment, a dry etcher is configured to etch using one or more magnetrons that are provided in close proximity to a substrate. The magnetron is scanned across the substrate to etch the desired areas of the substrate. The scanning magnetron can be used to effectively etch a substrate having a large surface area. As used herein, the term “on” is used broadly to include the meaning of both “overlying and in contact with a referenced object” and “overlying but not in direct contact with a reference object.”

In yet another embodiment, a dry etcher is configured to etch Indium Tin Oxide (ITO) films provided on flat panels using halogen-based chemistries. This apparatus and etch process associated with it are specifically designed to minimize the etch byproducts from being deposited on the chamber walls, thereby reducing the defects on the substrates and increasing the time between maintenance. The apparatus is scalable and capable of processing substrates that are a few inches to a few meters in dimension for the flat panel and semiconductor industries. For purpose of illustrating the present invention, specific embodiments relating to the ITO etcher are described below. However, the scope of the invention is not limited to ITO etching, as will be understood by those skilled in the art.

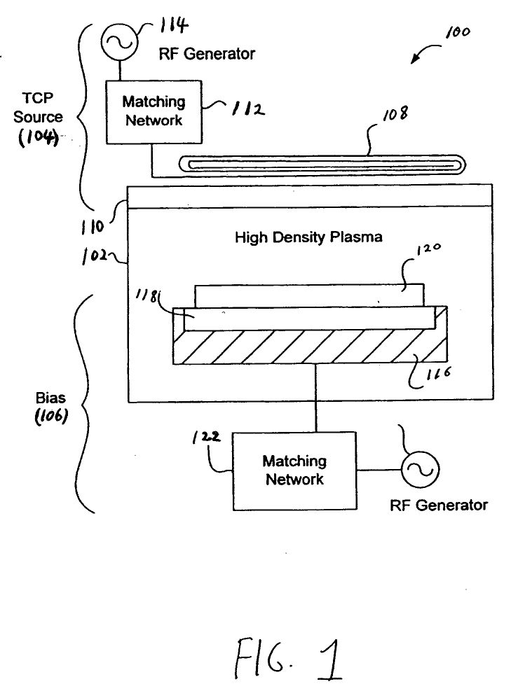

FIG. 1 illustrates a simplified diagram of a high density plasma etcher 100 including an inductively coupled plasma source. The plasma etcher 100 includes a chamber 102 which is powered by a TCP (transformer coupled plasma) source 104 and a RF bias 106. The TCP source 104 includes an RF generator 114 that couples to a matching network 112 and then to an RF coil 108. The RF coil 108 is coupled to a dielectric RF window 110 that is coupled to a top portion of the chamber 102. The RF bias 106 includes an RF generator 124 that is coupled to a matching network 122. Generally, the RF bias 106 is implemented to create a DC bias, which assists in directing charged plasma particles toward a substrate (or panel) 120. The matching network 122 is thus coupled to a bottom electrode 116, which typically includes an electrostatic chuck (ESC) 118 for securing the substrate 120 within the chamber 102. Other types of techniques for securing the substrate 120, such as mechanical clamps may also be used.

The plasma etcher 100 cannot effectively prevent generation of particles during the etch process because of its use of the dielectric window 110. On the one hand, the dielectric window is needed to enable the RF coil 108 to generate the plasma within the chamber 102. This plasma is used to etch the substrate 120. However, the dielectric window also makes it difficult to maintain a high uniform temperature within the chamber 102. High uniform inner wall temperature is needed to effectively limit the byproduct deposition on the chamber walls, so that particle generation can be minimized. The inner walls should be kept at least 180° Celsius, preferably at least 230° Celsius to keep etch byproducts vaporized during the etch process, so that they do not deposit on the walls. The byproducts accumulated on the walls eventually would fall off the walls and contaminate the substrate.

FIG. 2 illustrates a dry etcher (or plasma etcher) 200 that is configured to maintain a high inner wall temperature during an etch process according to one embodiment of the present invention. The apparatus or etcher 200 is a high density plasma (HDP) etcher and is configured to etch various materials including ITO, dielectrics, metals and semiconductors. Generally a HDP etcher achieves a high density plasma having a minimum average ion density of 10¹¹ cm⁻³ in the plasma. The etcher is compatible with a wide range of gaseous chemistries, including any halogen chemical compounds, hydrocarbons and oxygen. The chamber walls are made of corrosion resistant metals, such as anodized aluminum or stainless steel, or inorganic ceramic materials, or a combination thereof according to one embodiment of the present invention.

The etcher 200 includes an inner wall 202 that defines a process chamber 201 wherein a substrate 203 is processed using plasma 205 and an outer wall 204 that is joined to the inner wall using one or more thermal insulators 206. A plurality of resistive heaters 208 are coupled to the inner wall to heat the inner wall to a desired temperature. One or more gas injectors or ports 210 are coupled to the inner wall to provide process gas into the process chamber 201. One or more output ports 212 coupled to the process chamber 201 are used to remove gas and byproducts from the chamber. In the present implementation, an output port is provided on each side of the inner wall to more effectively remove the gas and byproducts from both sides of the process chamber.

A substrate holder 214 is configured to hold (or support) the substrate 203. The substrate holder may also be referred to as a substrate supporter. A radio-frequency (RF) source 216 is coupled to the substrate holder to provide a bias power to the substrate holder. One or more magnetrons 218 are provided in close proximity to the substrate 203 to locally increase the plasma density, from which the charged particles (e.g., ions) are extracted and accelerated across the plasma sheath toward the substrate and etch the exposed portions of the substrate (or the films deposited over the substrate). An insulator 220 is provided around the substrate holder to insulate the substrate holder and to maintain uniform equipotential electric field lines. A dark space shield 222 is provided below the substrate holder 214 and the insulator 220. A vacuum chamber 224 is defined below the dark space shield 222, so that the dark space shield separates the process chamber 201 and the vacuum chamber 224. A vacuum port 226 is coupled to the vacuum chamber to pump out the gas from the vacuum chamber and maintain it in substantially vacuum state, so that the pressure difference between the two chambers is minimized during the etch process.

As explained above, the etcher 200 includes two chambers, the process chamber 201 for processing the substrate and the vacuum chamber 224 for housing the scanning magnetron 218 in the present embodiment. The substrate holder 214 separates these two chambers. In another embodiment, the magnetron may be stored in a separate housing from the vacuum chamber.

The inner wall is configured to maintain high uniform temperature during etch process to limit the byproduct deposition on the chamber walls. The inner wall (or inner shell) 202 is configured to be heated to a high temperature, e.g., to 180° Celsius or more, 500° Celsius or more, 600° Celsius or more, 700° Celsius or more, 800° Celsius or more, 900° Celsius or more, or 1,000° Celsius or more. In the present implementation, the inner wall 202 is heated by resistive heaters 208 on the sides and the top of the inner wall 202. The temperature of the inner wall is controlled by adjusting the resistive heaters either individually or together. Using these heaters, the temperature of the process chamber 201 that is defined within the inner wall (or inner shell) may be kept at a high temperature to prevent the byproduct deposition on the inner wall. If the byproduct deposition on the inner wall is not controlled effectively, these byproducts quickly accumulate on the inner wall. They flake and drop onto the substrate being processed within the process chamber and cause a serious particle contamination issue.

To minimize the byproduct deposition on the inner wall, the process chamber temperature is kept high (e.g., between 100° Celsius to 600° Celsius) to keep the byproducts vaporized. The temperature needed to keep the byproducts vaporized differs for different etch processes since they typically produce different byproducts. In certain etch processes, the process chamber should be kept at least at 200° Celsius, or should be kept as high as 700° Celsius or more. The temperature of the process chamber corresponds to the temperature of the inner wall. Accordingly, the temperature of the process chamber is controlled by controlling the temperature of the inner wall. The temperature of the inner wall may be measured by using direct thermocouples or/and pyrometry depending on whether or not the inner wall is electrically grounded or floating.

The outer wall 204 is separated from the inner wall 202 by the thermal insulator 206, so that the temperature of the outer wall would not be too high. The outer wall may also be kept cool by using water.

In operation, the gaseous precursors are introduced into the process chamber through a plurality of gas injectors or ports 210, and are exhausted out through one or more exhaust ports 212 on the sides of the process chamber. Vacuum is achieved by using one or more turbo molecular pumps (not shown). In one implementation, cold traps are attached to the turbo molecular pumps to protect them from the byproducts, especially during the ITO etch process.

The substrate 203 is placed on the substrate holder 214, which is configured to move vertically to allow the substrate to be transferred in and out of the process chamber. The substrate temperature is controlled by flowing helium between the backside of the substrate and the substrate holder and adjusting the amount of helium flow. In the present implementation, the substrate temperature is configured to be controlled from below room temperature to a few hundred degrees Celsius. In the present implementation, the substrate holder is cooled with water, so that its temperature does not increase excessively from being exposed to the plasma during etch process.

The substrate holder 214 is electrically floating and connected to the RF power source 216. The dark space shield 222 is provided below the substrate holder and is electrically grounded. The dark space shield is provided in close proximity to the substrate holder in order to prevent a plasma discharge from being generated in the vacuum chamber 224. One or more insulators 220 extend from the substrate holder to the side of the vacuum chamber.

One or more magnetrons 218 are provided on the backside of the substrate holder to be scanned back and forth over the entire area of the substrate. If multiple magnetrons are used, the scanning distance and the etch time can be proportionally reduced. Each magnetron may comprise a single or multiple linear permanent magnets. The magnets may also be electromagnetic magnets.

In one embodiment, the magnetron assembly is configured so that the distance between the scanning magnetron and the substrate holder may be dynamically adjusted to control the intensity and shape of the magnetic field above the substrate surface. The magnetron assembly is located in a closed chamber, which can be at atmospheric pressure or under vacuum. The latter simplifies the design of the apparatus because fewer vacuum seals are needed between the substrate holder and the process chamber.

In the etcher or apparatus 200, a plasma is generated by the RF coupling to the substrate holder and the localized magnetic field generated by the magnetron 218. The plasma density is the highest in the localized magnetic field region that follows the moving magnet. The magnet is designed such that the plasma uniformity along its length is uniform. The plasma density within the high magnetic field region is high so the etch rate at that region is high. The plasma density in the area outside the high magnetic field region, however, is low, resulting in a slower etch rate at such a region. The etch rate at the region outside of the high magnetic field region should be sufficiently high to prevent redeposition of the byproducts on the substrate. An appropriate etch rate may be selected by adjusting the distance between the magnets and the substrate and by adjusting the RF power supplied to the substrate holder, among other conditions. The distance between the magnets and the substrate and the RF power supplied to the substrate holder affect the plasma density and the ion energy, which in turn affect the etch rate.

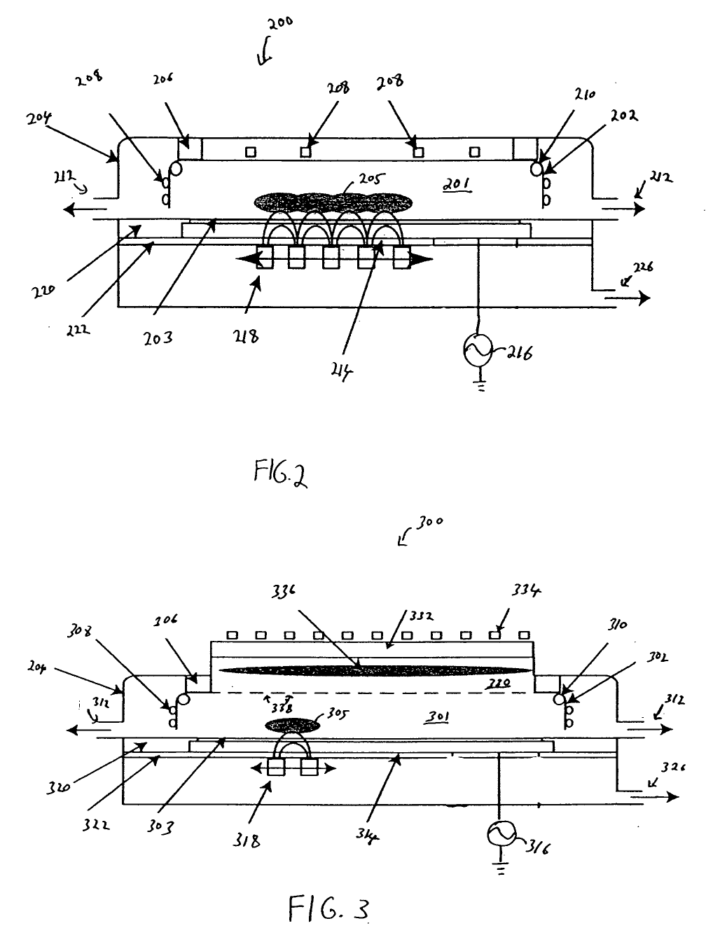

FIG. 3 illustrates a plasma etcher or apparatus 300 that is configured to maintain a high inner wall temperature during the etch process according to another embodiment of the present invention. The apparatus or etcher 300 may be used as a high density plasma etcher and etch various materials including ITO, dielectrics, metals and semiconductors. The etcher is compatible with a wide range of gaseous chemistries, including any halogen chemical compounds, hydrocarbons and oxygen. The chamber walls are made of corrosion resistant metals, such as anodized aluminum or stainless steel, or inorganic ceramic materials, or a combination thereof according to one embodiment of the present invention. In one implementation, the etcher 300 is configured to etch ITO films using chlorine as an etchant.

The etcher 300 includes an inner wall 302 that defines a process chamber 301 wherein a substrate 303 is processed using plasma 305 and an outer wall 304 that is joined to the inner wall using one or more thermal insulators 306. A plurality of resistive heaters 308 are coupled to the inner wall to heat the inner wall to a desired temperature. One or more gas injectors or ports 310 are coupled to the inner wall to provide process gas into the process chamber 301 defined by the inner wall. One or more output ports 312 coupled to the process chamber 301 are used to remove gas and byproducts from the chamber. In the present implementation, an output port is provided on each side of the inner wall to more effectively remove the gas and byproducts from both sides of the process chamber.

A substrate holder 314 is configured to hold (or support) the substrate 303. A radio-frequency (RF) source 316 is coupled to the substrate holder to provide a bias power to the substrate holder. One or more magnetrons 318 are provided in close proximity to the substrate 303 to generate a local high density plasma from which ions or charged particles are extracted and accelerated towards the substrate (or the films deposited over the substrate). An insulator 320 is provided around the substrate holder to insulate it and maintain uniform equipotential electric field lines. A dark space shield 322 is provided below the substrate holder 314 and the insulator 320. A lower chamber 324 is defined below the substrate holder 314. The dark space shield separates the lower chamber and the process chamber to prevent plasma generation in the lower chamber 324. The lower chamber 324 can be at atmospheric pressure or in vacuum, the latter easing the engineering constraints on the mechanical design. A vacuum port 326 is coupled to the chamber 324 to pump out the gas from the chamber and maintain it, preferably, in substantially vacuum state during etching.

Unlike the etcher 200, the etcher 300 includes an upper chamber 330 that is provided over the process chamber 301. The inner wall 302 separates the upper chamber and the process chamber. A dielectric window 332 is provided on top of the etcher 300 to define the upper side of the upper chamber 330. An RF antenna 334 is provided over the dielectric window to generate a high density plasma 336 within the upper chamber 330. The plasma 336 can be generated using a planar Transformer Coupled Plasma (TCP) or Inductively Coupled Plasma (ICP) coil. A plurality of inlets or holes 338 are defined on the upper side of the inner wall to allow portions of the plasma 336 (i.e., charged particles) to be injected into the process chamber 301. In one implementation, the heating of the inner wall in the region directly above the substrate may be supplemented by the heat from an additional heater or lamp (e.g., an infrared lamp). The plasma 336 may also be generated using TCP or ICP coil located on either side of the inner wall 302.

The upper chamber 330 provides an additional plasma source to pre-dissociate the gas and increase the overall density of the plasma 305 in the process chamber 301. The remote plasma can be any high density plasma source, fixed or scanned. The plasma source may be of various types, e.g., single or multiple helicon, ECR or ICP sources, or hollow cathodes. The plasma density of the remote plasma source can be controlled by adjusting the power applied to the RF antenna 334.

In one embodiment, the additional plasma source is located inside the process chamber and immediately facing the substrate. In such a configuration, the inner wall may be constructed without holes 338 since they are not needed for the diffusion or injection of charged particles into the process chamber.

In operation, a substrate, e.g., glass, with a coating of indium tin oxide (ITO) and a pre-patterned photo resist layer is loaded onto the substrate holder 214, 314 in the process chamber at atmospheric pressure. This may be done manually or with some type of mechanical robot. In another implementation, the loading is done at a low pressure or vacuum.

The process chamber is then closed and pumped down to a predetermined low pressure, e.g., 1×10⁻⁶ torr, by removing water vapor, oxygen and other gasses that may affect the subsequent etch process. The duration of this pumping process vary, e.g., from minutes to hours, depending on the surface area of the chamber walls, absorbed water and size of the mechanical and turbo-molecular pumps.

The substrate temperature is then set to a given temperature, if desired. When etching ITO, the inner chamber walls 202, 302 are heated to minimum of 180° Celsius, preferably at or above 230° Celsius to keep the byproducts mostly vaporized during the etch process. The temperature of the inner wall may be heated to a different temperature in other implementations, e.g., 300° Celsius or more, 350° Celsius or more, 400° Celsius or more, or 450° Celsius or more. In other implementations, the actual temperature of the process chamber may be measured and the inner wall is heated until a desired process chamber is obtained. The desired process chamber temperature vary according to application, e.g., 200° Celsius or more, 300° Celsius or more, 350° Celsius or more, 400° Celsius or more, or 450° Celsius or more.

A process gas, e.g., chlorine, is flowed into the process chamber using a mass flow controller (not shown). The process gas may also include inert gas, e.g., helium, argon, krypton, or a combination thereof. A down-stream pressure controller (not shown), which is provided between the process chamber and pump, sets the process chamber pressure to 1 to 10 milli-torr.

RF power is applied to the substrate holder 214, 314 supporting the substrate. The RF power applied should be sufficient to insure the etching of the entire substrate and that the etch rate is greater than the re-deposition rate during the magnetic scan. In the case of an additional plasma source, as illustrated in FIG. 3, that source can also be energized prior to the magnetic scan.

Once the plasma is stabilized, the magnets provided below the substrate holder are scanned across the entire substrate causing a high density plasma to form directly above the substrate as it scans. The high density plasma includes charged particles that are dissociated from the chlorine gas. These charged particles reacts with the ITO on the substrate to etch the exposed portions of the ITO. The low energy plasma (i.e., charged particles with a lower energy) elsewhere on the substrate keeps the byproducts from depositing on those areas. The etch process involves one or multiple passes of the magnets across the substrate according to application (e.g., depending on the depth of the desired etch, RF power applied to the substrate holder, and the speed of the magnetic scanning). An end point detection system may be used to automatically shut down the RF power being supplied to the substrate holder the detection system determines that the desired etch depth has been reached.

During the etch process, the inner chamber wall 202, 302 is maintained at a high temperature to keep most of the byproducts vaporized until they are exhausted out of the process chamber via the output ports 212, 312. As a result, the byproduct redeposition on the inner wall is minimized, and the particle contamination issue is effectively controlled.

Once the etch process has been completed, the RF etch power and process gas sources are shut off. The process chamber is evacuated and purged with nitrogen or inert gas to remove the chlorine residue. The chamber is then opened and the substrate removed.

The present invention has been illustrated using specific embodiments and implementations. The above embodiments and implementations are provided to fully disclose and enable those skilled in the art to understand and work the invention. They are not provided to give exhaustive variations or aspects of the invention. Those skilled in the art would understand that the embodiments and implementations above may be modified or altered without departing from the scope of the invention. For example, a vacuum load lock may be attached to the process chamber to keep the process chamber in vacuum during loading an removal of the substrate to decrease the pump-down time or even to eliminate it. The present invention may also be implemented in a multiple-chamber system, where each chamber is provided with its own load-lock. These multiple chambers may be arranged in a linear or cluster arrangement. A robot may be used to service these multiple chambers. The scope of the present invention should be interpreted using the appended claims.

What is claimed is:

1. A dry etcher, comprising:
a process chamber configured to process a substrate therein using plasma;
a substrate supporter to support the substrate; and
at least one magnetron provided in close proximity to the substrate and direct charged particles from the plasma to the substrate to etch the substrate.

2. The dry etcher of claim 1, further comprising:
a radio-frequency (RF) power source coupled to the substrate supporter, wherein the plasma is generated by the RF power applied to the substrate supporter and a magnetic field generated by the magnetron.

3. The dry etcher of claim 1, wherein the magnetron is provided below the substrate supporter and is configured to be scanned across the substrate, the substrate including a panel having a large surface area of at least 100 millimeter in a given direction.

4. The dry etcher of claim 3, wherein the substrate further includes a film deposited over the surface of the substrate, the film having a plurality of exposed portions and a plurality of covered portions, wherein the exposed portions are etched using the charged particles from the plasma.

5. The dry etcher of claim 4, wherein the film includes Indium Tin Oxide (ITO) and the plasma is generated from a halogen gas.

6. The dry etcher of claim 5, further comprising:
a first chamber wall configured to be heated to a high temperature to prevent etch byproducts from being deposited on the first chamber wall,
wherein the halogen gas includes chlorine.

7. The dry etcher of claim 1, further comprising:
a first chamber wall configured to be heated to a high temperature to prevent etch byproducts from being deposited on the first chamber wall.

8. The dry etcher of claim 7, wherein the first chamber wall is configured to be heated to at least 180° Celsius and is made of conductive material.

9. The dry etcher of claim 7, wherein the first chamber wall is configured to be heated to at least 230° Celsius to keep most of the byproducts vaporized until they are removed from the process chamber, the first chamber wall being made of conductive material

10. The dry etcher of claim 7, further comprising:
a second chamber wall provided outside of the first chamber wall, the first chamber wall being an inner wall and the second chamber wall being an outer wall, the first chamber wall defining the process chamber; and
an thermal insulator provided between the first and second chamber walls.

11. The dry etcher of claim 10, further comprising:
a lower chamber that is provided below the process chamber, the lower chamber housing the magnetron.

12. The dry etcher of claim 11, wherein the at least one magnetron comprises a plurality of magnetrons, each being configured to scan a selected region of the substrate.

13. The dry etcher of claim 11, further comprising:
an upper chamber provided above the process chamber, the upper chamber being configured to generated plasma therein; and
a plurality of holes provided on an upper side of the first chamber wall to enable portions of the plasma to be injected into the process chamber.

14. A plasma etcher configured to etch a substrate having a large surface area, the etcher comprising:
a process chamber configured to etch a substrate therein using plasma, the substrate including a panel and an Indium Tin Oxide (ITO) film;
a substrate supporter to support the substrate;
a first chamber wall defining the process chamber and being configured to be heated to a high temperature, the first chamber wall comprising conductive material; and
at least one magnetron provided in close proximity to the substrate and direct charged particles from the plasma to the substrate to etch the substrate.

15. The plasma etcher of claim 14, wherein the magnetron is provided below the substrate and is configured to be scanned across the substrate, the substrate having a dimension of at least 100 millimeters in a given direction.

16. The plasma etcher of claim 15, further comprising:
a lower chamber provided below the process chamber, the magnetron being housed within the lower chamber.

17. The plasma etcher of claim 14, further comprising:
a second chamber wall provided outside of the first chamber wall, wherein the substrate supporter is coupled to a radio-frequency power source.

18. The plasma etcher of claim 17, wherein the plasma is generated using the RF power applied to the substrate supporter and a localized magnetic field of the magnetron.

19. The plasma etcher of claim 14, wherein the substrate includes a patterned mask layer exposing portions of the ITO film, wherein the plasma is used to etch the exposed portions of the ITO film, the plasma being generated from a gas including chlorine.

20. A method for etching a substrate having a large surface area, the method comprising:
providing the substrate on a substrate support in an etch chamber, the etch chamber having a first chamber wall;
heating the first chamber wall to a given temperature that is sufficiently high to keep most of etch byproducts vaporized until they are removed from the etch chamber, so that byproduct accumulation on the first chamber wall is reduced;
generating plasma using at least one magnetron and a radio-frequency power source, the magnetron being provided below the substrate; and
etching the substrate using the generated plasma.
